(19) United States
(12) Patent Application Publication
(10) Pub. No.: US 2011/0048534 A1
(43) Pub. Date: Mar. 3, 2011

(54) Nanodipole Photovoltaic Devices, Methods of Making and Methods of Use Thereof

(75) Inventors: Diana Shvydka, Toledo, OH (US); Victor Karpov, Toledo, OH (US)

(73) Assignee: UNIVERSITY OF TOLEDO, Toledo, OH (US)

(21) Appl. No.: 12/863,074

(22) PCT Filed: Jan. 21, 2009
(86) PCT No.: PCT/US09/31524

§ 371 Date: Aug. 12, 2010

Related U.S. Application Data
(60) Provisional application No. 61/062,232, filed on Jan. 24, 2008.

(51) Int. Cl. H01L 31/0256; H01L 31/0296; H01L 31/0264; H01L 31/18; H01L 33/20; H01L 31/0352; H01L 29/06; H01L 29/861; H01L 29/68

(52) U.S. Cl. 136/258; 136/252; 136/260; 136/265; 438/63; 257/461; 257/618; 257/79; 257/E31.032; 257/E33.006; 257/E29.002; 257/E29.327; 257/E29.17; 977/773

(57) ABSTRACT

A photovoltaic device includes a built-in electric field generated by electric dipoles of nanoparticles embedded in a photoconducting host.

### CROSS-REFERENCE TO RELATED APPLICATIONS AND STATEMENT REGARDING SPONSORED RESEARCH

This application claims the benefit of U.S. Provisional Application No. 61/062,232 filed Jan. 24, 2008, the disclosure of which is incorporated herein by reference. This invention was not made with any government support and the government has no rights in this invention.

### TECHNICAL FIELD

The present invention concerns photovoltaic devices having a built-in electric field generated by electric dipoles of nanoparticles embedded in a photoconducting host.

### BACKGROUND OF THE INVENTION

Numerous types of photovoltaic devices and solar cells have been developed. In a first generation, photovoltaic devices were composed of, for example, crystalline materials which utilize a p-n junction built-in electric field. In order to create the electric field, there must be a perfect electric contact between p- and n-materials. In such crystalline photovoltaic devices, electron-hole pairs are generated in an absorber material that is exposed to light. An electric field separates photogenerated electron-hole pairs. The crystalline photovoltaic devices are fragile and expensive to manufacture.

In a second generation, photovoltaic devices that are composed of non-crystalline materials such as amorphous Si, polycrystalline CdTe and CuIn(Ga)Se2, also utilize a p-n junction (or likewise) built-in electric field. Again, these second generation photovoltaic devices also experience problems relating to a sufficient p-n interface. In addition, the technology needed to manufacture the amorphous silicon photovoltaic devices is usually complex, requiring vacuum deposition and post-deposition treatments. The second generation amorphous photovoltaic devices also experience nonuniformity and contacting issues, and are not very stable since the degradation rate is commercially dangerous. Also, the source materials (for example, Te, In, and “device quality Si”) are in limited supply.

In a third generation, photovoltaic devices which do not utilize p-n (or likewise) junction can be composed of electrochemical cells (Gretzel cells) or polymer blends with imbedded nano-particles that rely on diffusion which is an inefficient charge carrier collection.

Thus, there is a continuing need for improved photovoltaic devices that are stable, efficient and can be readily scaled up for commercial production.

There is also a continuing need for a method for making a more efficient, less expensive, and longer lasting photovoltaic device.

Thus, it would be advantageous to develop photovoltaic devices that overcome the limitations of the p-n junction photovoltaic devices.

It would also be advantageous if such photovoltaic devices were capable of being tunable in a broad range of parameters.

### SUMMARY OF THE INVENTION

In a broad aspect, there is provided a photovoltaic device that has a built-in electric field generated by electric dipoles of nanoparticles embedded in a photoconducting host.

In a broad aspect, the invention does not rely on p-n, Schottky or likewise junction to create the built-in electric field.

In a broad aspect, the invention does not require electric contact between two or more materials to generate the built-in electric field.

In a broad aspect, such a device with the built-in electric field generated by electric dipoles of nanoparticles can be used in non-photovoltaic applications as a type of diode or photodiode.

In a first broad aspect, there is provided herein a photovoltaic device that has a built-in electric field generated by electric dipoles of nanoparticles at least partially embedded in, or applied to, at least one photoconducting host material.

In certain embodiments, the photoconducting host is comprised of one or more of polymer, liquid, polycrystalline, or amorphous materials.

In certain embodiments, the built-in electric field is configured to be generated by aligned nano-size dipoles embedded in the photoconductive host.

In certain embodiments, the nanoparticles are comprised of one or more of: a strong pyro- and piezo-electric material or a ferroelectric material.

In certain embodiments, the nanoparticles are comprised one or more of: wurtzite CdS, CdSe, zinc-blended structured ZnSe and CdS particles, and ferroelectric materials including barium titanate with properly stabilized surfaces.

In certain embodiments, the nanoparticles have a substantially uniform generated field capable of being as strong as about 100 kV/cm, and capable of spatially separating photo-generated charge carriers.

In certain embodiments, the nanoparticles have a substantially uniform generated field capable of being tunable in a broad range of parameters and spectral characteristics.

In certain embodiments, the device is configured such that dipolar interactions lead to self-assemblies of dipole nanoparticles.

In certain embodiments, the device is configured such that the nanoparticles are strong enough to be substantially spontaneously polarized to create a built-in field, and yet not strong enough to cluster.

In certain embodiments, the nanoparticles have a mean size in the range of tens of nanometers.

In certain embodiments, exiting charge carriers in the host do not substantially suppress the dipole electric field by attaching to the dipole poles.

In certain embodiments, the nanoparticles are embedded in different hosts.

In certain embodiments, CdS nanoparticles are embedded in a CdTe host, thereby generating a strong built-in field without the use of junctions.

In certain embodiments, CdS nanoparticles are embedded into a CulInGaSe2 polycrystalline host.

In certain embodiments, the device includes a polymer matrix with one or more of embedded CdSe or CdS or ZnSe or BaTi nanoparticles.

In certain embodiments, the polymer material comprises one or more of PVK, or dye sensitized PVK, or other suitable photoconducting polymer.

In certain embodiments, the nanoparticles are added to dye-sensitized cells.

In another broad aspect, there is provided herein a photovoltaic system having a polymer or liquid photoconductive host containing nanodipoles suitable for application to a conductive surface and for forming a photovoltaic device upon addition of a top electrode.

In another broad aspect, there is provided herein a method for creating an electric field for photovoltaic applications, comprising using one or more of the device described herein.

In another broad aspect, there is provided herein a method for creating an electric field for photovoltaic applications, comprising using one or more of the systems described herein.

In another broad aspect, there is provided herein a photovoltaic material capable of being tunable in a broad range of parameters, comprising one or more devices described herein.

In certain embodiments, i) the dipole generated field is strong; ii) the device remains uniform such that the nanodipoles do not aggregate; and iii) the dipole fields are not suppressed by existing charge carriers.

In another broad aspect, there is provided herein a method of making a photovoltaic device, comprising using a non-vacuum printing process for depositing the nanoparticles onto a substrate.

In another broad aspect, there is provided herein a method of making a photovoltaic using a non-vacuum printing process for depositing a mixture of dipole nanoparticles and at least one photoconducting host material onto a substrate.

In certain embodiments, the photovoltaic device includes a mixture of CdTe and polar CdS nano-powders.

In certain embodiments, the device is configured for use in a non-photovoltaic application.

In certain embodiments, the device is configured for one or more of: a diode and/or photodiode function.

In certain embodiments, the device is configured for one or more functions, including an electric current rectification application, light detection and/or generation, and an electronic memory application.

Various objects and advantages of this invention will become apparent to those skilled in the art from the following detailed description of the preferred embodiment, when read in light of the accompanying drawings.

### BRIEF DESCRIPTION OF THE DRAWING

FIGS. 1A-1B are schematic illustrations of: FIG. 1A—CdS particles (of arbitrarily chosen cylinder shape) with pyroelectric charges responsible for its dipole (p) properties; FIG. 1B—aligned electric dipoles (solid arrows) and electric field lines (E; dashed arrows) caused by polarization.

FIG. 2 is a schematic illustration of electric dipole (gray arrow) and its first image charge counterparts in the metal electrodes (fat lines) for the cases of (a) dipole parallel to the electrode planes; and, (b) dipole perpendicular to the electrode planes. Secondary and higher order images (of images) are not shown.

FIG. 3 is a schematic illustration of an example of the energy band diagram and sketch of operations of nanodipole PV. Shown in the diagram are also HOMO and LUMO for a possible sensitizing dye molecule. Vertical arrows represent the photoexcitation processes in the dye and nanoparticle materials. The dashed arrows show that charge carriers can move out of the plane.

FIG. 4 is a schematic illustration showing a Prior Art photovoltaic device made by a vacuum deposition process.

FIG. 5 is a schematic illustration showing a photovoltaic device made by a non-vacuum process.

### DETAILED DESCRIPTION OF THE PREFERRED EMBODIMENT

In a broad aspect, there is provided herein an improved photovoltaic device that uses a “built-in” electric field generated by aligned nanosize dipoles in a photoconductive host. In a particular aspect, the photoconductive host can be polymer or liquid, or amorphous, or polycrystalline.

In a broad aspect, polymer or liquid photoconductive hosts containing nanodipoles can be made in the form of paint applicable to any conductive surface (such as that of car, building, TCO/glass) to form a photovoltaic device after the top electrode is added upon that paint.

In a broad aspect, various non-photovoltaic applications of the nanodipole based built-in electric field include a new type of diodes or photodiodes not relying on p-n or Schottky, or similar junctions.

In another broad aspect, there is provided herein a device useful in non-photovoltaic applications, such as various diode and photodiode functions, including the electric current rectification, light detection and generation, and electronic memory applications.

In a particular aspect, the non-photovoltaic applications the invention can be used for various diode and photodiode functions including the electric current rectification, light detection and generation, and electronic memory.

The nanoparticle dipoles have a substantially uniform generated field tunable in a broad range of parameters and spectral characteristics.

The nanoparticle dipoles do not have to form a good electric contact with the host.

Non-limiting examples of suitable dipole materials include one or more of wurtzite CdS, CdSe, zinc-blended structured ZnSe and CdS particles, and ferroelectric materials including barium titanate with properly stabilized surfaces. In certain embodiments, the nanoparticle size is in the range of tens of nanometers.

In other non-limiting examples, CdS, CdSe or other nano-dipole particles can be used with proper coating protecting their surface charges and polarities.

In certain embodiments, the dipoles have a substantially uniform generated field capable of being as strong as 100 kV/cm, and capable of spatially separating photo-generated charge carriers.

In a particular aspect, the photovoltaic device is configured such that dipolar interactions lead to self-assemblies of dipole nanoparticles. The device can be configured such that nano dipoles are strong enough to be spontaneously polarized (aligned) to create a built-in field, and yet not too strong to cluster.

Also, in a particular aspect, the device is configured such that exiting charge carriers do not suppress the dipole electric field by attaching to the dipole poles.

In certain non-limiting examples, the dipole nanoparticles are embedded in different hosts. For example, properly stabilized CdS nano-dipoles can be embedded in a CdTe host, thereby generating a strong built-in field without the use of junctions. In another example, they are embedded into a CuInGaSe₂ polycrystalline host.

In other non-limiting examples, the photovoltaic device includes a polymer matrix with one or more of embedded CdSe or CdS or ZnSe or BaTi nanoparticles. The polymer matrix can comprise one or more of PVK, or dye sensitized PVK, or other suitable photo-conducting polymer. In other examples, the nanodipoles can be added to dye-sensitized Gretzel cells.

In another broad aspect, there is provided herein use dipole nano-particles to create a strong electric field for photovoltaic applications.

It is to be understood that the photovoltaic devices as described herein are capable of being tunable in a broad range of parameters. Also, it is to be understood that i) the dipole generated field is strong; ii) the system remains uniform such that the nanodipoles do not aggregate; and iii) the dipole fields are not suppressed by the existing charge carriers.

In certain embodiments, the generated field can be uniform and strong enough (i.e., in a non-limiting example, 1-3×10⁴ V/cm) to separate electron-hole pairs and run significant drift currents. The nanodipole photovoltaic suggested structure does not utilize p-n or Schottky junctions and can be tunable in a broad range of parameters.

In one broad aspect, there is provided herein a photovoltaic device where semiconductor nanoparticles are electric dipoles in the polymer or other matrix, including amorphous, polycrystalline, and even liquid substances. The semiconductor nanoparticles can be found in wurtzite CdS and CdSe and similar strong pyro- and piezo-electric materials. In certain embodiments, ferroelectric nanoparticles can be also be used. The polarization surface charges can be related to the chemically different surfaces such as the Cd (electrically more positive) and the S. terminated (more negative) surfaces in CdS.

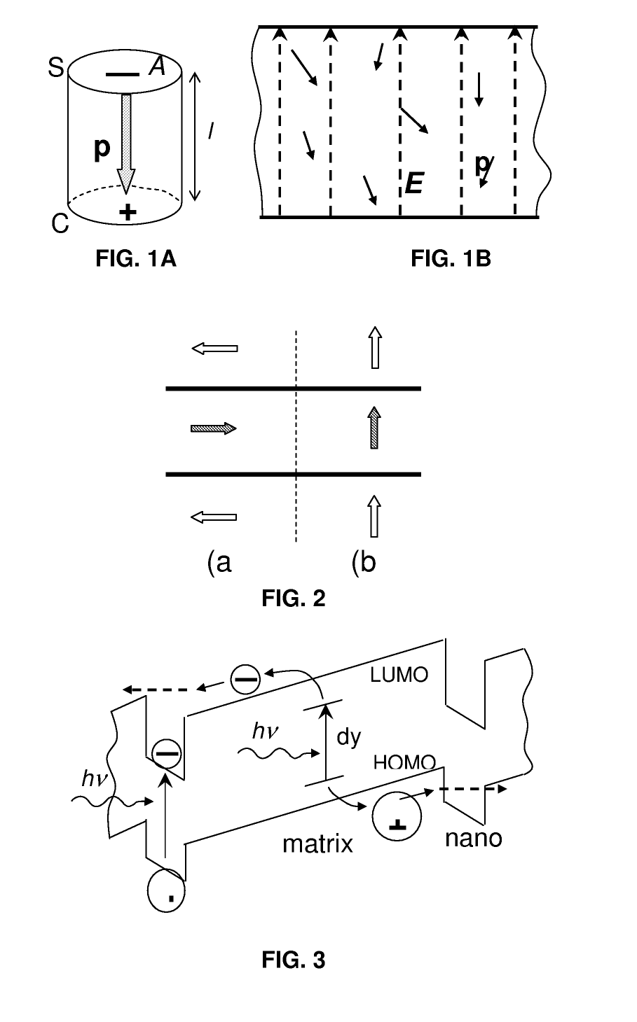

The pyro-(piezo)effects in CdS as shown in FIGS. 1A-1B can strongly impact operations of thin-film CdTe/CdS and CuIn(Ga)Se₂/CdS photovoltaics.

The nanoparticles can inherit the wurtzite structure of their bulk counterparts. Properly stabilized CdSe nanoparticles have permanent dipole moments as would be expected from their wurtzite structure origin. Furthermore, not only wurtzite but zinc-blended ZnSe and CdS particles exhibit large permanent dipole moments approximately linear in their sizes, which may be an intrinsic attribute of many nonmetal nanoparticles with surface localized charges. Also, dipolar interactions can lead to self-assemblies of nanoparticles.

As disclosed herein, the inventors have estimated the characteristic dipole moment of a single CdS or CdSe wurtzite nanoparticle as a function of its size.

The inventors used the pyroinduced surface charge density σ˜10¹²e/cm², where e is the electron charge, known for bulk crystals. It corresponds to the surface charge σA and the dipole moment p=σ/A=σΩ, where A, 1, and Ω are, respectively, the particle face area, length, and volume. The typical linear sizes of available CdS particles are in the range of 0.01-0.1 μm. Assuming, for example, a 10 nm size range yields Ω˜10³ nm³ and p=100e Å, consistent with the data for CdSe nanoparticles.

Dipoles of concentration n create the average field,

$$E = \frac{4 π}{ɛ} pn = \frac{4 π}{ɛ} σ f ≡ {E}_{max} f \qquad ( 1 )$$

where ∈ is the dielectric permittivity of a matrix, f=ηΩ is the dimensionless volume fraction occupied by the dipole particles, and Eₘₐₓ is the electric field strength for a hypothetical uniform polarization with f=1. Assuming ∈˜5 and σ˜10¹² e/cm² yields Eₘₐₓ˜3·10⁵ V/cm. For f˜0.1, the field strength Eₘₐₓ˜3·10⁴ V/cm is comparable to strong p-n junctions.

The energy of a single field-aligned dipole is

$$w = - p \cdot E = - \frac{4 {πσ}^{2} Ω}{ɛ} f . \qquad ( 2 )$$

The desired strong polarization takes place when

|w|>>kT (3)

where k is the Boltzmann constant and T is the temperature. Substituting here the above assumed parameters and f˜0.1 yields |w|˜0.0.25 eV much higher than the room temperature kT˜25 meV. Such a strong inequality |w|>>kT shows that there exists a broad range of parameters f and Ω, for which the system is polarized.

The strong interdipole interaction |w|>>kT makes the system capable of spontaneous polarization. In the mean-field approximation, |w|/k=T_{c} plays the role of the Curie temperature, below which the spontaneous polarization takes place. The direction of such a polarization is determined by anisotropy factors in the system, in particular, by the dipole interactions with flat metal electrodes, as illustrated in FIG. 2.

The energy difference between the cases of polarization perpendicular and parallel to the electrodes is due to the dipole interactions with their induced electrode polarization, similar to the image charge effect. Since the dipole-dipole interaction strongly decays with distance r, an estimate can be obtained based on the first order image charge approximation neglecting secondary and higher order images induced by the first images in the opposite electrodes. Also, because the energy of interaction between two dipoles p₁ and p₂ is proportional to p₁·p₂−3(p₁·r)(p₂·r)/r², the polarization perpendicular to the electrode [p₁=p2 p₂⊥r; see FIG. 2(b)] has two times lower energy than that of the parallel polarization [p₁=p2 p₂∥r; see FIG. 2(a)]. The energetically favorable perpendicular polarization remains frustrated between the up and down directions. The latter uncertainty can be eliminated by temporarily applying the external electric field. Overall, the inventors show that there can be strong spontaneous polarization and the built-in electric field perpendicular to the system electrodes.

Another effect of strong interactions is aggregation (clustering) of dipole particles. The trend of aggregation is clearly seen from Eq. (2) where the dipole energy |w| increases with f (i.e., dipole concentration). Because this effect creates nonuniformity, it appears detrimental to the system PV performance.

The condition, under which the aggregation remains insignificant, and how it determines the upper bound of f, is described below.

The electrostatic energy F₁=Nw/2 of N=ηV in a system of volume V decreases when f increases. Assuming local fluctuation δf in volume fraction above its average f̅, the corresponding electrostatic energy gain is expressed as

$$δ {F}_{1} = w \frac{V}{Ω} \overline{f} δ f . \qquad ( 4 )$$

On the other hand, such increase in f will lead to the corresponding increase in the entropy part of the free energy, F₂=[flNf+(1−f)ln(1−f)]kTV/Ω. Assuming δf/f<<1, the latter increase is estimated as

$$δ {F}_{2} = \frac{kT}{2} \frac{V}{Ω} \frac{δ {f}^{2}}{\overline{f}} . \qquad ( 5 )$$

The total free energy is δF=δF₁+δF₂ is a minimum at

$$δ f = \frac{\vert w \vert}{kT} {\overline{f}}^{2} . \qquad ( 6 )$$

It is observed that the fluctuation δf remains relatively small,

δf/ f̅<<1 when |w|<<kT/ f̅.

It is to be noted that, by the virtue of the same argument, the dipoles will not sediment at the electrode surfaces.

Combining |w|<<kT/ f̅ with the condition of strong polarization in Eq. (3) yields the criterion of spatially uniform strongly polarized system of nanodipoles,

kT<<|w|<<kT/ f̅, (7)

which can always be satisfied because of f̅<<1.

Using Eqs. (1) and (2), the inequalities in Eq. (7) can be represented in the terms of electric field,

$$\frac{{E}_{Ω}^{2}}{{E}_{max}} ≪ E ≪ {E}_{Ω} , {E}_{Ω} ≡ \sqrt{\frac{4 π kT}{{Ω}_{ɛ}}} . \qquad ( 8 )$$

Here, E_{Ω} has the physical meaning of the highest electric field compatible with the condition of uniform system.

It is desired to seek for E_{Ω} as close as possible to the above estimated: Eₘₐₓ˜3·10⁵ V/cm. In particular, the field strength E_{Ω}˜10⁵ V/cm appears to be consistent with the inequalities in Eq. (8) and high enough to force significant drift currents. The latter field corresponds to the particle volume Ω˜10³ nm³, which predicts the nanodipole size l₀˜10 nm to be most suitable for PV applications.

Particles much smaller than l₀ are not strong enough dipoles to provide a significant polarization (|w|≲kT); on the other hand, much larger particles will have to be limited in volume fraction to avoid aggregation, which limitation decreases the field strength.

In certain embodiments, the above description may be limited to the case of neutral nanoparticles. In other embodiments, they can be charged due to the difference in chemical potentials between the host and the particle materials. The Coulomb repulsion will suppress the particle aggregation thereby relaxing the limitation on the particle upper size. The larger particles (l>l₀) will create even a stronger built-in field than the above estimated.

Also, in certain embodiments, the details of operations of the nanodipole PV can, at least in part, depend on the energy band structure and other parameters of both nanoparticles and the matrix.

In the example of FIG. 3, the diagram proportions are chosen to reflect a particular case of CdSe particles (energy gap≈1.8 eV) embedded in the polyvinyl-carbazole polymer, with the gap of ≈3.5 eV between the highest occupied molecular orbital (HOMO) and the lowest unoccupied molecular orbital (LUMO). The electron-hole generation can be facilitated by dye sensitizing also illustrated in FIG. 3. In general, both the particles and the host can contribute to the electron-hole photogeneration.

Field reversal between the host and nanoparticle material in FIG. 3 is a general feature related to the polarization interfacial charge σ. While the intraparticle field may seem to oppose the average electric current, the dipole particles occupy a small volume fraction f<<1, so that the electrons and holes move mostly through the host material.

With respect to possible electrostatic screening of the dipole fields, the inventors note that under open circuit conditions, the field is always screened not only in the system under consideration, but in any PV. The question of matter concerns the nonequilibrium conditions characterized by a certain current density j≈10 mA/cm² flowing through the typical PV system. Screening in such a system can develop by attaching the opposite type of particles to the dipole poles. This effect remains insignificant until the ratio of the charge carrier trapping over detrapping times is large, τₜ/τ_{dt}>>1. These times can be estimated as τ_{dt}˜e/jR² and τ_{dt}˜τ₀ exp(W/kT), where the potential barrier W≈eEₘₐₓR and τ₀˜10⁻¹³ s is the characteristic atomic vibration time, and R is the particle linear size. Using the above numerical parameters yields τₜ/τ_{dt}>>1, hence, screening is insignificant.

In spite of a polymer related motif in FIG. 3, nanodipole PV can be useful with many other materials including the combinations of CdTe/CdS and CuIn(Ga)Se₂/CdS, as are currently used as polycrystalline thin-film PV. The corresponding nanodipole PV as described herein could, for example, be properly stabilized CdS dipole nanoparticles embedded in CdTe or CuIn(Ga)Se₂ matrix. In certain embodiments, these PV systems can be created by inexpensive screen printing technology.

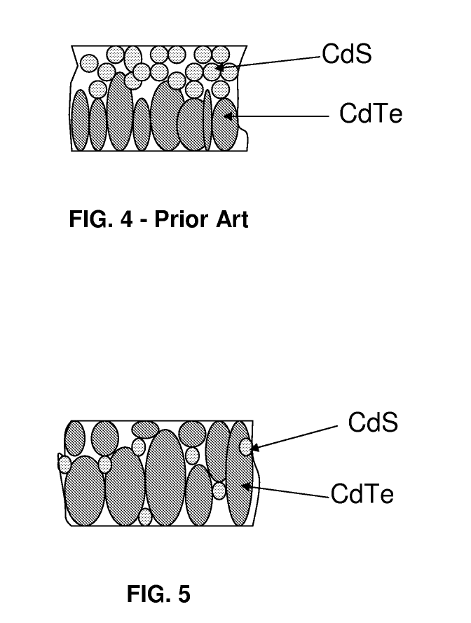

Referring now to FIG. 4, there is schematically illustrated a Prior Art photovoltaic device made by a vacuum deposition process which includes separate vacuum deposition steps for the deposit of a CdTe film and a CdS film. In order for such Prior Art photovoltaic device to be effective, the electric contact between the two films is crucial.

In contrast, FIG. 5 shows a schematic illustration of a photovoltaic device made by a one step non-vacuum printing process where the photovoltaic device includes a mixture of CdTe and polar CdS nano-powders. The photovoltaic device made using such one step non-vacuum printing process does not require electric contact between the CdTe and CdS components.

Thus, there is provided herein photovoltaics utilizing the electric field of nanodipoles where the fields are comparable to that of strong p-n junction devices. Also, in certain embodiments, the photovoltaics can be made using size particles l₀˜10 nm. In addition, the dipole photovoltaic system is spatially uniform and implementable with many different types of PV.

The foregoing has outlined in broad terms the more important features of the invention disclosed herein so that the detailed description that follows may be more clearly understood, and so that the contribution of the instant inventor to the art may be better appreciated. The instant invention is not to be limited in its appreciation to the details of the construction and to the arrangements of the components set forth in the description herein or illustrated in the drawings herein. Rather, the invention is capable of other embodiments and of being practiced and carried out in various other ways not specifically enumerated herein.

It should be understood that the phraseology and terminology employed herein are for the purpose of description and should not be regarded as limiting, unless the specification specifically so limits the invention.

Also, while the invention has been described with reference to various and preferred embodiments, it should be understood by those skilled in the art that various changes may be made and equivalents may be substituted for elements thereof without departing from the essential scope of the invention. In addition, many modifications may be made to adapt a particular situation or material to the teachings of the invention without departing from the essential scope thereof. Therefore, it is intended that the invention not be limited to the particular embodiment disclosed herein contemplated for carrying out this invention, but that the invention will include all embodiments falling within the scope of the claims.

### REFERENCES

The publication and other material used herein to illuminate the invention or provide additional details respecting the practice of the invention, are incorporated by reference herein, and for convenience are provided in the following bibliography.

Citation of any of the documents recited herein is not intended as an admission that any of the foregoing is pertinent prior art. All statements as to the date or representation as to the contents of these documents is based on the information available to the applicant and does not constitute any admission as to the correctness of the dates or contents of these documents.
S. E. Gledhill, B. Scott, and B. A. Gregg, J. Mater. Res. 20, 3167 (2005); E. Arici, D. Meissner, F. Scilffer, and N. S. Sariciftci, Int. J. Photoenergy 5, 199 (2003).
D. Berlincourt, H. Jaffer, and L. R. Shiozawa, Phys. Rev. 129, 1009 (1963).
W. J. Mink-us, Phys. Rev. 138, A1277 (1965).
J. D. Zook and S. T. Liu, J. Appl. Phys. 49, 4604 (1978).
F. A. Pizzarello, J. Appl. Phys. 38, 1752 (1967).
T. Ohno, D. Suzuki, H. Suzuki, and T. Ida, J. Soc. Powder. Technol. Jpn. 41, 86 (2004).
M. Mitra, J. Drayton, M. L. C. Cooray, V. G. Karpov, and D. Shvydka, J. Appl. Phys. 102, 034505 (2007).
J. Nanda, K. S. Narayan, B. A. Kuntvilla, G. L. Murthy, and D. D. Sarnia, Appl. Phys. Lett. 72, 1335 (1998).
S. A. Blanton, R. L. Leheny, M. A. Hines, and P. Guyot-Sionnest, Phys. Rev. Lett. 79, 865 (1997); M. E. Schmidt, S. A. Blanton, M. A. Hines, and P. Guyot-Sionnest, J. Chem. Phys. 106, 5254 (1997).
E. Rabani, B. Hetenyi, B. J. Berne, and L. E. Bras, J. Phys. Chem. 110, 5355 (1999).
M. Shim and P. Guyot-Sionnest, J. Phys. Chem. 111, 6955 (1999).
S. Shanbhag and N. A. Kotov, J. Phys. Chem. B 110, 12211 (2006).
X. Zhang, Z. Zhang, and S. C. Glotzer, J. Phys. Chem. C 111, 4132 (2007); M. Klokkenburg, A. J. Houtepen, R. Koole, J. W. J. deFolter, B. H. Erne, E. van Faassen, and D. Vanmaekelbergh, Nano Lett. 7, 2931 (2007).
J. D. Jackson, Classical Electrodynamics (Wiley, N.Y., 1999).
L. D. Landau and E. M. Lifshitz, Statistical Physics (Pergamon, N.Y., 1980).
F. Li, D.-1. Son, S.-M. Seo, H.-M. Cha, H.-J. Kim, B: J. Kim, J. H. Jung, T. W. Kim. Anal. Phys. Lett. 91, 122111 (2007).

What is claimed is:

1. A photovoltaic device comprising a built-in electric field generated by electric dipoles of nanoparticles at least partially embedded in, or applied to, at least one photoconducting host.

2. The device of claim 1, wherein the photoconducting host is comprised of one or more of: polymer, liquid, polycrystalline, or amorphous materials.

3. The device of claim 1, wherein the built-in electric field is configured to be generated by aligned the dipole nanoparticles embedded in the photoconductive host.

4. The device of claim 1, wherein the nanoparticles are comprised of one or more of: a strong pyro- and piezo-electric material or a ferroelectric material.

5. The device of claim 1, wherein the nanoparticles are comprised one or more of: wurtzite CdS, CdSe, zinc-blended structured ZnSe and CdS particles, and ferroelectric materials including barium titanate with properly stabilized surfaces.

6. The device of claim 1, wherein the nanoparticles have a substantially uniform generated field capable of being as strong as about 100 kV/cm, and capable of spatially separating photo-generated charge carriers.

7. The device of claim 1, wherein the nanoparticles have a substantially uniform generated field capable of being tunable in a broad range of parameters and spectral characteristics.

8. The device of claim 1, wherein the device is configured such that dipolar interactions lead to self-assemblies of pyroelectric nanoparticles.

9. The device of claim 1, wherein the device is configured such that the nanoparticles are strong enough to be substantially spontaneously polarized to create a built-in field, and yet not strong enough to cluster.

10. The device of claim 1, wherein the nanoparticles have a mean size in the range of tens of nanometers.

11. The device of claim 1, wherein exiting charge carriers in the host do not substantially suppress the dipole electric field by attaching to the dipole poles.

12. The device of claim 1, wherein the nanoparticles are embedded in different hosts.

13. The device of claim 1, wherein CdS nanoparticles are embedded in a CdTe host, thereby generating a strong built-in field without the use of junctions.

14. The device of claim 1, wherein CdS nanoparticles are embedded into a CuInGaSe₂ polycrystalline host.

15. The device of claim 1, wherein the device includes a polymer matrix with one or more of embedded CdSe or CdS or ZnSe or BaTi nanoparticles.

16. The device of claim 1, wherein the polymer material comprises one or more of PVK, or dye sensitized PVK, or other suitable photoconducting polymer.

17. The device of claim 1, wherein the nanoparticles are added to dye-sensitized cells.

18. A photovoltaic system comprising a polymer or liquid photoconductive host containing nanodipoles suitable for application to a conductive surface and for forming a photovoltaic device upon addition of a top electrode.

19. A method for creating an electric field for photovoltaic applications, comprising using the device of claim 1.

20. A method for creating an electric field for photovoltaic applications, comprising using the system of claim 18.

21. A photovoltaic material capable of being tunable in a broad range of parameters, comprising the device of claim 1.

22. The device of claim 1, wherein i) the dipole generated field is strong; ii) the device remains uniform such that the nanodipoles do not aggregate; and iii) the dipole fields are not suppressed by existing charge carriers.

23. A method of making a photovoltaic device of claim 1, using a non-vacuum printing process for depositing a mixture of the dipole nanoparticles and at least one photoconducting host material onto a substrate.

24. The method of claim 23, wherein the photovoltaic device includes a mixture of CdTe and polar CdS nano-powders.

25. The device of claim 1, configured for use in a non-photovoltaic application.

26. The device of claim 25, wherein the device is configured for one or more of: a diode and/or photodiode function.

27. The device of claim 26, wherein the device is configured for one or more functions, including an electric current rectification application, light detection and/or generation, and an electronic memory application.
